(19) United States
(12) Patent Application Publication
(10) Pub. No.: US 2013/0134038 A1
(43) Pub. Date: May 30, 2013

(54) Ferromagnetic Material Sputtering Target

(71) Applicants: Atsushi Sato, Ibaraki (JP); Hideo Takami, Ibaraki (JP)

(72) Inventors: Atsushi Sato, Ibaraki (JP); Hideo Takami, Ibaraki (JP)

(73) Assignee: JX NIPPON MINING & METALS CORPORATION, Tokyo (JP)

(21) Appl. No.: 13/814,776

(22) PCT Filed: Jan. 28, 2011
(86) PCT No.: PCT/JP2011/051775

§ 371 Date: Feb. 7, 2013

(30) Foreign Application Priority Data
Sep. 3, 2010 (JP) 2010-197887

(51) Int. Cl. C23C 14/34

(52) U.S. Cl. CPC C23C 14/3414
USPC 204/298.13

(57) ABSTRACT

A ferromagnetic material sputtering target which is a sintered compact sputtering target made of a metal having Co as its main component, and nonmetallic inorganic material particles, wherein a plurality of metal phases having different saturated magnetization exist, and the nonmetallic inorganic material particles are dispersed in the respective metal phases. By increasing the pass-through flux of the sputtering target, it is possible to obtain a stable discharge. Moreover, it is also possible to obtain a ferromagnetic material sputtering target capable of obtaining a stable discharge in a magnetron sputtering device and which has a low generation of particles during sputtering. Thus, this invention aims to provide a ferromagnetic material sputtering target for use in the deposition of a magnetic thin film of a magnetic recording medium, and particularly of a magnetic recording layer of a hard disk adopting the perpendicular magnetic recording system.

### BACKGROUND

The present invention relates to a ferromagnetic material sputtering target for use in the deposition of a magnetic thin film of a magnetic recording medium, and particularly of a magnetic recording layer of a hard disk adopting the perpendicular magnetic recording system, and to a nonmetallic inorganic material particle-dispersed ferromagnetic material sputtering target with low generation of particles which has a large pass-through flux and which is able to obtain stable electrical discharge when sputtered with a magnetron sputtering device.

Incidentally, the term “sputtering target” is sometimes abbreviated as “target” in the ensuing explanation, but please note that these two terms have substantially the same meaning.

In the field of magnetic recording as represented with hard disk drives, a material based on Co, Fe or Ni as ferromagnetic metals is used as the material of the magnetic thin film which is used for the recording. For example, Co—Cr-based or Co—Cr—Pt-based ferromagnetic alloys with Co as its main component are used for the recording layer of hard disks adopting the longitudinal magnetic recording system.

Moreover, composite materials of Co—Cr—Pt-based ferromagnetic alloys with Co as its main component and nonmagnetic, nonmetallic inorganic material particles are often used for the recording layer of hard disks adopting the perpendicular magnetic recording system which was recently put into practical application.

A magnetic thin film of a magnetic recording medium such as a hard disk is often produced by sputtering a ferromagnetic material sputtering target having the foregoing materials as its components in light of its high productivity.

As a method of manufacturing this kind of ferromagnetic material sputtering target, the melting method or powder metallurgy may be considered. It is not necessarily appropriate to suggest which method is better since it will depend on the demanded characteristics, but a sputtering target made of ferromagnetic alloys and nonmagnetic, nonmetallic inorganic material particles used for the recording layer of hard disks adopting the perpendicular magnetic recording system is generally manufactured with powder metallurgy. This is because the nonmetallic inorganic material particles need to be uniformly dispersed within the alloy substrate, and this is difficult to achieve with the melting method.

For example, proposed is a method of obtaining a sputtering target for a magnetic recording medium including the steps of mixing Co powder, Cr powder, TiO₂ powder and SiO₂ powder, mixing the obtained mixed powder and Co spherical powder with a planetary-type mixer, and molding the mixed powder with hot pressing (Patent Document 1).

With the target structure in the foregoing case, a spherical metal phase (B) having magnetic permeability that is higher than the peripheral structure can be observed in a metallic substrate phase (A) in which nonmetallic inorganic material particles are uniformly dispersed (FIG. 1 of Patent Document 1). This kind of structure entails the problems described later, and it is not necessarily favorable as a sputtering target for a magnetic recording medium.

Moreover, proposed is a method of obtaining a sputtering target for a Co-based alloy magnetic film including the steps of mixing SiO₂ powder with Co—Cr—Ta alloy powder prepared with the atomization method, subsequently performing mechanical alloying thereto with a ball mill to disperse the oxides in the Co—Cr—Ta alloy powder, and molding this with hot pressing (Patent Document 2).

Although the drawings are unclear, the target structure in the foregoing case comprises a shape in which black portions (SiO₂) are surrounding a large, white spherical structure (Co—Cr—Ta alloy). This kind of structure is also not necessarily favorable as a sputtering target for a magnetic recording medium.

In addition, proposed is a method of obtaining a sputtering target for forming a thin film for use in a magnetic recording medium including the steps of mixing Co—Cr binary system alloy powder, Pt powder and SiO₂ powder, and hot pressing the obtained mixed powder (Patent Document 3).

Although the target structure in the foregoing structure is not shown in the drawings, it is described that a Pt phase, a SiO₂ phase and a Co—Cr binary system alloy phase are visible, and that a diffusion layer can be observed around the Co—Cr binary system alloy layer. This kind of structure is also not necessarily favorable as a sputtering target for a magnetic recording medium.

There are various types of sputtering devices, but a magnetron sputtering device comprising a DC power source is broadly used in light of its high productivity for the deposition of the foregoing magnetic recording film. This sputtering method causes a positive electrode substrate and a negative electrode target to face each other, and generates an electric field by applying high voltage between the substrate and the target under an inert gas atmosphere.

Here, the sputtering method employs a fundamental principle where inert gas is ionized, plasma composed of electrons and positive ions is formed, and the positive ions in the plasma collide with the target (negative electrode) surface so as to sputter the atoms configuring the target. The discharged atoms adhere to the opposing substrate surface, wherein the film is formed. As a result of performing the sequential process described above, the material configuring the target is deposited on the substrate.

[Patent Document 1] Japanese Patent Application No. 2010-011326

[Patent Document 2] Japanese Unexamined Patent Application Publication No. H10-088333

[Patent Document 3] Japanese Unexamined Patent Application Publication No. 2009-1860

### SUMMARY OF THE INVENTION

### Problems to be Solved by the Invention

Generally, if a magnetron sputtering device is used to sputter a ferromagnetic material sputtering target, since much of the magnetic flux from the magnet will pass through the target, which is a ferromagnetic body, the pass-through flux will decrease, and there is a major problem in that a discharge does not occur during the sputtering or, the discharge is unstable even if a discharge does occur.

In order to overcome this problem, known is a method of inputting coarse metal grains of approximately 30 to 150 μm during the production process of the sputtering target in order to intentionally obtain an uneven target structure. Nevertheless, in the case, when the ratio of coarse metal grains increases, the ratio of the nonmetallic inorganic material particles in the mother phase material will increase, and the nonmetallic inorganic material particles are more easily flocculated. The flocculated portion of the nonmetallic inorganic material particles entails problems in that abnormal discharge occurs and particles (foreign particles that adhered to the substrate) are generated during sputtering. Moreover, there are cases where an abnormal discharge occurs at the interface thereof and causes the generation of particles since there is a difference in the erosion speed between the metal phase and the mother phase.

As described above, conventionally, even with magnetron sputtering, it was possible to obtain a stable discharge by reducing the relative permeability of the sputtering target and increasing the pass-through flux. However, the generation of particles during sputtering tended to increase.

In light of the foregoing problems, an object of this invention is to provide a ferromagnetic material sputtering target capable of obtaining a stable electrical discharge when sputtered with a magnetron sputtering device, with low generation of particles, and with improved pass-through flux.

### Means for Solving the Problems

As a result of intense study to achieve the foregoing object, the present inventors discovered that a target with a large pass-through flux and with low generation of particles can be obtained by adjusting the target structure.

Based on the foregoing discovery, the present invention provides:
1) A ferromagnetic material sputtering target which is a sintered compact sputtering target made of a metal having Co as its main component, and nonmetallic inorganic material particles, wherein a plurality of metal phases having different saturated magnetization exist, and the nonmetallic inorganic material particles are dispersed in the respective metal phases.

The present invention additionally provides:
2) The ferromagnetic material sputtering target according to 1 above, wherein the metal phase having the highest saturated magnetization among the plurality of metal phases having different saturated magnetization takes on a form of a dispersed material, and the remaining metal phases take on a form of a dispersion medium.

The present invention additionally provides:
3) The ferromagnetic material sputtering target according to 2 above, wherein the metal phase having the highest saturated magnetization has a size of 30 μm or more and 250 μm or less, and an average aspect ratio of 1:2 to 1:10.

The present invention additionally provides:
4) The ferromagnetic material sputtering target according to any one of 1 to 3 above, wherein the nonmetallic inorganic material particles are an oxide, a nitride, a silicide or a carbide of one or more components selected among Cr, Ta, Si, Ti, Zr, Al, Nb and B, or carbon.

The present invention additionally provides:
5) The ferromagnetic material sputtering target according to any one of 1 to 4 above, wherein the ferromagnetic material sputtering target comprises a dimension and a shape in which a value obtained by dividing an outer peripheral length of the nonmetallic inorganic material particles by an area of the nonmetallic inorganic material particles in a cutting plane of the sputtering target is 0.4 or more.

Needless to say, the foregoing plurality of metal phases having different saturated magnetization include alloy phases.

### Effect of the Invention

The present invention yields a superior effect of being able to obtain a stable discharge by increasing the pass-through flux of the sputtering target, particularly a ferromagnetic material sputtering target capable of obtaining a stable discharge in a magnetron sputtering device and which has a low generation of particles during sputtering.

### BEST MODE FOR CARRYING OUT THE INVENTION

The ferromagnetic material sputtering target of the present invention is a sintered compact sputtering target made of a metal having Co as its main component, and nonmetallic inorganic material particles. As a result of a plurality of metal phases having different saturated magnetization existing, and the nonmetallic inorganic material particles being dispersed in the respective metal phases, it is possible to obtain a ferromagnetic material sputtering target capable of maintaining a high pass-through flux and reducing the generation of particles. Needless to say, the foregoing plurality of metal phases having different saturated magnetization include alloy phases.

As a preferred ferromagnetic material sputtering target of the present invention, recommended is a sintered compact sputtering target made of a metal having a composition in which Cr is 5 mol % or higher and 20 mol % or less, and the remainder is Co, and nonmetallic inorganic material particles. The metal components are caused to achieve a composition where Cr is 5 mol % or higher and 20 mol % or less, and the remainder is Co; this is because characteristics as a nonmetallic inorganic material particle-dispersed ferromagnetic material will deteriorate if Cr is less than 5 mol % or exceeds 20 mol %.

As another preferred sputtering target of the present invention, a sintered compact sputtering target made of the following is recommended: a metal having a composition in which Cr is 5 mol % or higher and 20 mol % or less, Pt is 5 mol % or higher and 30 mol % or less, and the remainder is Co, and nonmetallic inorganic material particles.

The metal components are caused to achieve a composition where Cr is 5 mol % or higher and 20 mol % or less, Pt is 5 mol % or higher and 30 mol % or less, and the remainder is Co; this is because characteristics as a nonmetallic inorganic material particle-dispersed ferromagnetic material will deteriorate if Cr is less than 5 mol % or exceeds 20 mol %, or if Pt is less than 5 mol % or exceeds 30 mol %.

Moreover, with the ferromagnetic material sputtering target of the present invention, the metal phase having the highest saturated magnetization among the plurality of metal phases having different saturated magnetization may taken on a form of a dispersed material, and the remaining metal phases may take on a form of a dispersion medium. As a result of adopting this kind of structure, it is possible to realize an even higher pass-through flux.

Moreover, with the present invention, the metal phase having the highest saturated magnetization may have a size of 30 μm or more and 250 μm or less, and an average aspect ratio of 1:2 to 1:10. This structure is particularly unique in that the leakage magnetic field becomes large and particles are not generated easily. Accordingly, this structure is particularly effective for enabling a stable discharge in a magnetron sputtering device and reducing the generation of particles.

As the nonmetallic inorganic material particles, an oxide, a nitride, a silicide or a carbide of one or more components selected among Cr, Ta, Si, Ti, Zr, Al, Nb and B, or carbon may be used. Desirably, the additive amount of the foregoing nonmetallic inorganic material particles is, as a total amount, less than 50% of the volume ratio in the target.

The target structure of the present invention is characterized in comprising a dimension and a shape in which a value obtained by dividing an outer peripheral length of the nonmetallic inorganic material particles by an area of the nonmetallic inorganic material particles in a cutting plane of the sputtering target is 0.4 (1/μm) or more. Generally speaking, since nonmetallic inorganic material particles have higher electrical resistance in comparison to metals, charge tends to become accumulated during sputtering, and this causes the generation of arcing. When the nonmetallic inorganic material particles comprise a dimension and a shape In which a value obtained by dividing an outer peripheral length of the nonmetallic inorganic material particles by an area of the nonmetallic inorganic material particles is 0.4 (1/μm) or more, charge is not easily accumulated, and this is particularly effective for reducing the generation of arcing and the generation of particles. The outer peripheral length and area of the nonmetallic inorganic material particles can be obtained by polishing an arbitrary cutting plane of the target, and analyzing the image obtained upon observing the polished surface thereof with an optical microscope or an electron microscope. By setting the field of view in the foregoing case to 10000 μm² or more, variations based on the observed site can be reduced.

The ferromagnetic material sputtering target of the present invention is prepared via the powder sintering method. Foremost, a compound particle powder in which nonmetallic inorganic material particles are dispersed in a metal base material is prepared in a plurality of compositions. Here, the respective compound particle powders are prepared so that the saturated magnetization will differ. Subsequently, the compound particle powders are weighed and mixed to achieve the intended target composition, whereby sintering powder is obtained. The sintering powder is sintered via hot press or the like to prepare the sintered compact for the sputtering target of the present invention.

As the starting raw materials, a metal powder and a nonmetallic inorganic material powder are used. Desirably, the metal powder to be used has a maximum grain size of 20 μm or less. Moreover, instead of using a single element metal powder, it is also possible to use an alloy powder. In the foregoing case also, desirably, the alloy powder to be used has a maximum grain size of 20 μm or less.

Meanwhile, if the grain size is too small, there is a problem in that the oxidation of the metal powder is promoted and the component composition will not fall within the required scope, and therefore, the grain size is desirably 0.5 μm or more.

Desirably, the nonmetallic inorganic material powder to be used has a maximum grain size of 5 μm or less. It is also desirable to use nonmetallic inorganic material powder having a grain size of 0.1 μm or more, since the nonmetallic inorganic material powder tends to flocculate when the grain size is too small. Several types of compound particle powders having different compositions are prepared with the following procedure, and then mixed.

Foremost, the foregoing metal powder and nonmetallic inorganic material powder are weighed. Here, a plurality of lots having a different nominal composition are prepared. Subsequently, for the respective lots, the weighed metal powder and nonmetallic inorganic material powder are pulverized and mixed using a known method such as with a ball mill. And, these mixed powders are calcined to obtain a calcined compact in which the nonmetallic inorganic material particles are dispersed in the metal base material. The calcination may be performed using a baking furnace, or pressure calcination may be performed via hot press. Subsequently, the calcined compact is pulverized using a pulverizer to obtain a compound particle powder in which the nonmetallic inorganic material particles are dispersed in a metal base material. Desirably, the average grain size of the compound particle powder is made to be 20 μm or more, upon performing the pulverization,.

The compound particle powders of the plurality of compositions prepared as described above are weighed to achieve the intended target composition, and mixed using a mixer. Here, a ball mill having high crush strength is not used in order to prevent the compound particle powder from becoming pulverized. As a result of not finely pulverizing the compound particles, the diffusion of the compound particle powder during sintering can be inhibited, and it is possible to obtain a sintered compact having a plurality of metal phases of different saturated magnetization. In addition to the above, it is also possible to mix the compound particle powder and a mixed powder (mixed powder of metal powder and nonmetallic inorganic material particle powder) to obtain a target.

The sintering powder obtained as described above is molded and sintered via hot press. Methods such as the plasma discharge sintering method and hot isostatic sintering method may also be used in addition to hot press. The holding temperature during sintering is preferably set to the lowest temperature in the temperature range in which the target will become sufficiently densified. While this often depends on the composition of the target, in many cases, the foregoing temperature falls within a temperature range of 900 to 1300° C. Based on the foregoing process, it is possible to produce a sintered compact for a ferromagnetic material sputtering target.

### EXAMPLES

The present invention is now explained in detail with reference to the Examples and Comparative Examples. Note that these Examples are merely illustrative and the present invention shall in no way be limited thereby. In other words, various modifications and other embodiments are covered by the present invention, and the present invention is limited only by the scope of its claims.

### Example 1

In Example 1, as the metal raw material powder, a Co powder having an average grain size of 3 pm and a Cr powder having an average grain size of 5 μm were prepared; and as the nonmetallic inorganic material particle powder, a SiO₂ powder having an average grain size of 1 μm was prepared. These powders were weighed to achieve the following composition ratios.

92 Co-8 SiO₂ (mol %) Composition 1-1:

68 Co-24 Cr-8 SiO₂ (mol %) Composition 1-2:

Subsequently, the respectively weighed powders of Composition 1-1 and Composition 1-2 were placed in a ball mill pot with a capacity of 10 liters together with zirconia balls as the grinding medium, and rotated and mixed for 20 hours.

The respective mixed powders of Composition 1-1 and Composition 1-2 were filled in a carbon mold, and hot pressed in a vacuum atmosphere under the following conditions; namely, temperature of 800° C., holding time of 2 hours, and pressure of 30 MPa to obtain a sintered compact. The respective sintered compacts were pulverized using a jaw crusher and a grindstone-type pulverizer. In addition, the respective pulverized powders were sieved using a sieve having sieve openings of 20 μm and 53 μm to obtain the respective compound particle powders of Composition 1-1 and Composition 1-2 in which the grain size is within the range of 20 to 53 μm.

Subsequently, with respect to Composition 1-1 and Composition 1-2, the respective compound particle powders were weighed so that the composition of the overall target would be 80 Co-12 Cr-8 SiO₂ (mol %), and mixed for 10 minutes using a planetary-type mixer having a ball capacity of approximately 7 liters in order to obtain a sintering powder.

The sintering powder obtained as described above was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm.

The measurement of the pass-through flux was performed according to ASTM F2086-01 (Standard Test Method for Pass Through Flux of Circular Magnetic Sputtering Targets, Method 2). The pass-through flux density measured by fixing the target center and rotating it 0 degrees, 30 degrees, 60 degrees, 90 degrees, and 120 degrees was divided by the value of the reference field defined in the ASTM and represented in percentage by multiplying 100 thereto. The result of averaging the foregoing five points was used as the average pass-through flux density (%).

The average pass-through flux density of the target of Example 1 was 52%. Upon observing the structure of this target, a plurality of metal phases having a different composition existed, and it was confirmed that the nonmetallic inorganic material particles were dispersed in the respective metal phases.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 6 particles.

### Example 2

In Example 2, as the metal raw material powder, a Co powder having an average grain size of 3 μm and a Cr powder having an average grain size of 5 μm were prepared; and as the nonmetallic inorganic material particle powder, a SiO₂ powder having an average grain size of 1 μm was prepared. These powders were weighed to achieve the following composition ratios.

92 Co-8 SiO₂ (mol %) Composition 2-1:

68 Co-24 Cr-8 SiO₂ (mol %) ti Composition 2-2:

Subsequently, the weighed powders of Composition 2-1 were placed in a ball mill pot with a capacity of 10 liters together with zirconia balls as the grinding medium, and rotated and mixed for 20 hours.

This mixed powder was filled in a carbon mold, and hot pressed in a vacuum atmosphere under the following conditions; namely, temperature of 800° C., holding time of 2 hours, and pressure of 30 MPa to obtain a sintered compact. This sintered compact was pulverized using a jaw crusher and a grindstone-type pulverizer. In addition, the pulverized powder was sieved using a sieve having sieve openings of 75 μm and 150 μm to obtain a compound particle powder in which the grain size is within the range of 75 to 150 μm.

Subsequently, with respect to Composition 2-2, the weighed Co powder and Cr powder and SiO₂ powder were placed in a ball mill pot with a capacity of 10 liters together with zirconia balls as the grinding medium, and rotated and mixed for 20 hours. The formation of compound particles via calcination was not performed in Composition 2-2.

The compound particle powder of Composition 2-1 and the mixed powder of Composition 2-2 were weighed so that the composition of the overall target would be 80 Co-12 Cr-8 SiO₂ (mol %), and mixed for 10 minutes using a planetary-type mixer having a ball capacity of approximately 7 liters in order to obtain a sintering powder.

The sintering powder obtained as described above was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 54%.

Upon observing the structure of this target, a plurality of metal phases having a different composition existed, and it was confirmed that the nonmetallic inorganic material particles were dispersed in the respective metal phases.

It was additionally confirmed that the metal phase having the highest Co content considered to have the highest saturated magnetization exists in matrix as a dispersed material.

Moreover, the size of the metal phase considered to have the highest saturated magnetization was 75 μm or more and 150 μm or less, and it was confirmed that the average aspect ratio is roughly 1:4.

In the cutting plane of the sputtering target, the value obtained by dividing the outer peripheral length of the nonmetallic inorganic material particles by the area of the nonmetallic inorganic material particles was 0.4 or more.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 6 particles.

### Comparative Example 1

In Comparative Example 1, as the metal raw material powder, a Co powder having an average grain size of 3 μm, a Cr powder having an average grain size of 5 μpm, and a Co spherical powder having a grain size within the range of 75 to 150 μm were prepared; and as the nonmetallic inorganic material particle powder, a SiO₂ powder having an average grain size of 1 pm was prepared. These powders were weighed to achieve the target composition of 80 Co-12 Cr-8 SiO₂ (mol %). The blending ratio of the Co powder and the Co spherical powder in the foregoing case was 3:7.

Subsequently, the Co powder and the Cr powder and the SiO₂ powder were placed in a ball mill pot with a capacity of 10 liters together with zirconia balls as the grinding medium, and rotated and mixed for 20 hours. In addition, the obtained mixed powder and the Co spherical powder were mixed for 10 minutes using a planetary-type mixer having a ball capacity of approximately 7 liters.

This mixed powder was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 53%. Moreover, in this target structure, a metal phase in which the nonmetallic inorganic material particles are not dispersed therein, which corresponds to the Co spherical powder, was occasionally observed. This structure is outside the scope of the present invention.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 17 particles.

### Comparative Example 2

In Comparative Example 2, as the metal raw material powder, a Co powder having an average grain size of 3 μm and a Cr powder having an average grain size of 5 μm were prepared; and as the nonmetallic inorganic material particle powder, a SiO₂ powder having an average grain size of 1 μm was prepared. These powders were weighed to achieve the target composition of 80 Co-12 Cr-8 SiO₂ (mol %).

Subsequently, these powders were placed in a ball mill pot with a capacity of 10 liters together with zirconia balls as the grinding medium, and rotated and mixed for 20 hours.

Subsequently, this mixed powder was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 46%. Moreover, this target structure was a structure in which the nonmetallic inorganic material particles are dispersed in a uniform alloy phase.

In the cutting plane of the sputtering target, the value obtained by dividing the outer peripheral length of the nonmetallic inorganic material particles by the area of the nonmetallic inorganic material particles was less than 0.4.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 5 particles.

The results of the foregoing Examples and Comparative Examples were compared; while Comparative Example 1 had an average pass-through flux density that was substantially equivalent to Examples 1 and 2, the number of particles during sputtering had increased. Moreover, while the number of particles of Comparative Example 2 was substantially equivalent to Examples 1 and 2, the average pass-through flux density was small, and it is anticipated that problems such as unstable sputtering will arise when the thickness of the target is increased in order to extend the target life.

### Example 3

In Example 3, as the metal raw material powder, a Co powder having an average grain size of 3 μm, a Cr powder having an average grain size of 5 μm, and a Pt powder having an average grain size of 2 μm were prepared; and as the nonmetallic inorganic material particle powder, a SiO₂ powder having an average grain size of 1 μpm and a Cr₂O₃ powder having an average grain size of 3 μm were prepared. These powders were weighed to achieve the following composition ratios.

45.71 Co-45.71 Pt-8.58 Cr₂O₃ (mol %) Composition 3-1:

45.45 Co-45.45 Cr-9.10 SiO₂ (mol %) Composition 3-2:

93.02 Co-6.98 SiO₂ (mol %) Composition 3-3:

Subsequently, the respectively weighed powders of Composition 3-1, Composition 3-2, and Composition 3-3 were placed in a ball mill pot with a capacity of 10 liters together with zirconia balls as the grinding medium, and rotated and mixed for 20 hours.

The respective mixed powders of Composition 3-1, Composition 3-2, and Composition 3-3 were filled in a carbon mold, and hot pressed in a vacuum atmosphere under the following conditions; namely, temperature of 800° C., holding time of 2 hours, and pressure of 30 MPa to obtain a sintered compact. The respective sintered compacts were pulverized using a jaw crusher and a grindstone-type pulverizer. In addition, the respective pulverized powders were sieved using a sieve having sieve openings of 20 μm and 53 μm to obtain the respective compound particle powders of Composition 3-1, Composition 3-2, and Composition 3-3 in which the grain size is within the range of 20 to 53 μm.

Subsequently, with respect to Composition 3-1, Composition 3-2, and Composition 3-3, the respective compound particle powders were weighed so that the composition of the overall target would be 66 Co-10 Cr-16 Pt-5 SiO₂-3 Cr₂O₃ (mol %), and mixed for 10 minutes using a planetary-type mixer having a ball capacity of approximately 7 liters in order to obtain a sintering powder.

The sintering powder obtained as described above was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this was 48%. Upon observing the structure of this target, a plurality of metal phases having a different composition existed, and it was confirmed that the nonmetallic inorganic material particles were dispersed in the respective metal phases.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 5 particles.

### Example 4

In Example 4, as the metal raw material powder, a Co powder having an average grain size of 3 μm, a Cr powder having an average grain size of 5 μm, and a

Pt powder having an average grain size of 2 μm were prepared; and as the nonmetallic inorganic material particle powder, a SiO₂ powder having an average grain size of 1 μm and a Cr₂O₃ powder having an average grain size of 3 μm were prepared. These powders were weighed to achieve the following composition ratios.

2.31 Co-7.69 SiO₂ (mol %) Composition 4-1:

49.18 Co-16.39 Cr-26.23 Pt-3.28 SiO₂-4.92 Cr₂O₃ (mol %) Composition 4-2:

Subsequently, the weighed powders of Composition 4-1 were placed in a ball mill pot with a capacity of 10 liters together with zirconia balls as the grinding medium, and rotated and mixed for 20 hours. This mixed powder was filled in a carbon mold, and hot pressed in a vacuum atmosphere under the following conditions; namely, temperature of 800° C., holding time of 2 hours, and pressure of 30 MPa to obtain a sintered compact. This sintered compact was pulverized using a jaw crusher and a grindstone-type pulverizer. In addition, the pulverized powder was sieved using a sieve having sieve openings of 75 μm and 150 μm to obtain a compound particle powder in which the grain size is within the range of 75 to 150 μm.

Subsequently, with respect to Composition 4-2, the weighed powders were placed in a ball mill pot with a capacity of 10 liters together with zirconia balls as the grinding medium, and rotated and mixed for 20 hours. The formation of compound particles via calcination was not performed in Composition 4-2.

The obtained compound particle powder of Composition 4-1 and the mixed powder of Composition 4-2 were weighed so that the composition of the overall target would be 66 Co-10 Cr-16 Pt-5 SiO₂-3 Cr₂O₃ (mol %), and mixed for 10 minutes using a planetary-type mixer having a ball capacity of approximately 7 liters in order to obtain a sintering powder.

The sintering powder obtained as described above was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 50%.

Upon observing the structure of this target, a plurality of metal phases having a different composition existed, and it was confirmed that the nonmetallic inorganic material particles were dispersed in the respective metal phases.

It was additionally confirmed that the metal phase having the highest Co content considered to have the highest saturated magnetization exists in matrix as a dispersed material.

Moreover, the size of the metal phase considered to have the highest saturated magnetization was 75 pm or more and 150 μm or less, and it was confirmed that the average aspect ratio is roughly 1:4.

In the cutting plane of the sputtering target, the value obtained by dividing the outer peripheral length of the nonmetallic inorganic material particles by the area of the nonmetallic inorganic material particles was 0.4 or more.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 3 particles.

### Comparative Example 3

In Comparative Example 3, as the metal raw material powder, a Co powder having an average grain size of 3 μm, a Cr powder having an average grain size of 5 μm, a Pt powder having an average grain size of 3 μm, and a Co spherical powder having a grain size within the range of 75 to 150 pm were prepared; and as the nonmetallic inorganic material particle powder, a SiO₂ powder having an average grain size of 1 μm and a Cr₂O₃ powder having an average grain size of 3 μm were prepared. These powders were weighed to achieve the target composition of 66 Co-10 Cr-16 Pt-5 SiO₂-3 Cr₂O₃ (mol %). The blending ratio of the Co powder and the Co spherical powder in the foregoing case was 1:2.

Subsequently, the Co powder, the Cr powder, the Pt powder, the SiO₂ powder, and the Cr₂O₃ powder were placed in a ball mill pot with a capacity of 10 liters together with zirconia balls as the grinding medium, and rotated and mixed for 20 hours. In addition, the obtained mixed powder and the Co spherical powder were mixed for 10 minutes using a planetary-type mixer having a ball capacity of approximately 7 liters.

This mixed powder was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 48%. In this target structure, a metal phase in which the nonmetallic inorganic material particles are not dispersed therein, which corresponds to the Co spherical powder, was occasionally observed, however, this structure is outside the scope of the present invention.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 18 particles.

### Comparative Example 4

In Comparative Example 4, as the metal raw material powder, a Co powder having an average grain size of 3 μm and a Cr powder having an average grain size of 5 μm were prepared; and as the nonmetallic inorganic material particle powder, a SiO₂ powder having an average grain size of 1 μm and a Pt powder having an average grain size of 3 μm were prepared. These powders were weighed to achieve the target composition of 66 Co-10 Cr-16 Pt-5 SiO₂-3 Cr₂O₃ (mol %).

Subsequently, these powders were placed in a ball mill pot with a capacity of 10 liters together with zirconia balls as the grinding medium, and rotated and mixed for 20 hours.

Subsequently, this mixed powder was filled in a carbon mold, and hot pressed in a vacuum atmosphere under the following conditions; namely, temperature of 1100° C., holding time of 2 hours, and pressure of 30 MPa to obtain a sintered compact. This sintered compact was further cut with a lathe to obtain a disk-shaped target having a diameter of 180 mm and thickness of 5 mm. The average pass-through flux density of this target was 41%. Moreover, this target structure was a structure in which the nonmetallic inorganic material particles are dispersed in a uniform alloy phase.

In the cutting plane of the sputtering target, the value obtained by dividing the outer peripheral length of the nonmetallic inorganic material particles by the area of the nonmetallic inorganic material particles was less than 0.4.

Subsequently, the target was mounted on a DC magnetron sputtering device and then sputtered. The sputtering conditions were as follows; namely, sputter power of 1 kW and Ar gas pressure of 1.5 Pa, and, after performing pre-sputtering of 2 kWhr, sputtering was performed to deposit a film having a target film thickness of 1000 nm on a silicon substrate having a 4-inch diameter. In addition, the number of particles that adhered to the substrate was measured using a particle counter. The number of particles on the silicon substrate in this case was 3 particles.

The results of the foregoing Examples and Comparative Examples were compared; while Comparative Example 3 had an average pass-through flux density that was substantially equivalent to Examples 3 and 4, the number of particles during sputtering had increased considerably. Moreover, while the number of particles of Comparative Example 4 was substantially equivalent to Examples 3 and 4, the average pass-through flux density was small, and it is anticipated that problems such as unstable sputtering will arise when the thickness of the target is increased in order to extend the target life.

In comparison to a sputtering target having a structure of two or more phases in which an inorganic material is dispersed in one phase, the product of the present invention has the same level of PTF (leakage magnetic field), which is slightly higher if the composition is the same but the generation of particles is extremely low. In addition, in comparison to a sputtering target that does not have a structure of two or more phases, the product of the present invention obviously has a higher PTF (leakage magnetic field), and the generation of particles is substantially the same. Namely, the advantage of the product of the present invention lies in that the present invention was able to realize the reduction of particles and a high leakage magnetic field.

### INDUSTRIAL APPLICABILITY

The present invention is useful as a ferromagnetic material sputtering target for use in the deposition of a magnetic thin film of a magnetic recording medium, and particularly of a magnetic recording layer of a hard disk adopting the perpendicular magnetic recording system, since the present invention yields a superior effect of being able to obtain a stable discharge by increasing the pass-through flux of the sputtering target, particularly a ferromagnetic material sputtering target capable of obtaining a stable discharge in a magnetron sputtering device and which has a low generation of particles during sputtering.

1. A ferromagnetic material sputtering target which is a sintered compact sputtering target made of a metal having Co as its main component, and nonmetallic inorganic material particles, wherein a plurality of metal phases having different saturated magnetization exist, and the nonmetallic inorganic material particles are dispersed in the respective metal phases, a metal phase having the highest saturated magnetization among the plurality of metal phases having different saturated magnetization is in a form of a dispersed material, and the remaining metal phases are in the form of a dispersion medium.

2. (canceled)

3. The ferromagnetic material sputtering target according to claim 1, wherein the metal phase having the highest saturated magnetization has a size of 30 μm or more and 250 μm or less, and an average aspect ratio of 1:2 to 1:10.

4. The ferromagnetic material sputtering target according to claim 3, wherein the nonmetallic inorganic material particles are an oxide, a nitride, a silicide or a carbide of one or more components selected among Cr, Ta, Si, Ti, Zr, Al, Nb and B, or carbon.

5. The ferromagnetic material sputtering target according to claim 4, wherein the ferromagnetic material sputtering target comprises a dimension and a shape in which a value obtained by dividing an outer peripheral length of the nonmetallic inorganic material particles by an area of the nonmetallic inorganic material particles in a cutting plane of the sputtering target is 0.4 or more.

6. The ferromagnetic material sputtering target according to claim 1, wherein the nonmetallic inorganic material particles are an oxide, a nitride, a silicide or a carbide of one or more components selected among Cr, Ta, Si, Ti, Zr, Al, Nb and B, or carbon.

7. The ferromagnetic material sputtering target according to claim 1, wherein the ferromagnetic material sputtering target comprises a dimension and a shape in which a value obtained by dividing an outer peripheral length of the nonmetallic inorganic material particles by an area of the nonmetallic inorganic material particles in a cutting plane of the sputtering target is 0.4 or more.

8. A ferromagnetic material sputtering target which is a sintered compact sputtering target made of a metal having Co as its main component, and nonmetallic inorganic material particles, wherein a plurality of metal phases having different saturated magnetization exist, the nonmetallic inorganic material particles are dispersed in the respective metal phases, and the ferromagnetic material sputtering target comprises a dimension and a shape in which a value obtained by dividing an outer peripheral length of the nonmetallic inorganic material particles by an area of the nonmetallic inorganic material particles in a cutting plane of the sputtering target is 0.4 or more.
